(19) United States
(12) Patent Application Publication
(10) Pub. No.: US 2026/0269004 A1
(43) Pub. Date: Sep. 10, 2026

(54) METHOD FOR STORING DATA IN A MEMORY DEVICE THAT INCLUDES DEFECTIVE MEMORY BLOCKS

(71) Applicant: Microchip Technology Incorporated, Chandler, AZ (US)

(72) Inventors: Hayes Hsueh, San Jose, CA (US); Pitamber Shukla, San Jose, CA (US); Salvatrice Scommegna, Cornate D'Adda (IT); Srinivas Yelisetti, Fremont, CA (US)

(73) Assignee: Microchip Technology Incorporated, Chandler, AZ (US)

(21) Appl. No.: 19/224,049

(22) Filed: May 30, 2025

Related U.S. Application Data
(60) Provisional application No. 63/767,315, filed on Mar. 5, 2025.

(51) Int. Cl. G11C 29/00; G11C 16/10; G11C 16/34

(52) U.S. Cl. CPC G11C 29/88; G11C 16/102; G11C 16/349

(57) ABSTRACT

A computer-implemented method for storing data in a memory device that includes a plurality of planes of data storage, with each plane including a plurality of blocks of data storage, comprises identifying a plurality of defective blocks within the memory device; and issuing a multiplane program command that includes the actual data to be stored in one or more viable plane(s) and false data to be stored in one or more defective plane(s), the one or more defective plane(s) each including one or more of the plurality of defective blocks.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/767,315; titled “METHOD FOR STORING DATA IN A MEMORY DEVICE THAT INCLUDES BAD MEMORY BLOCKS”; and filed Mar. 5, 2025. The Provisional Application is hereby incorporated by reference, in its entirety, into the current patent application.

### FIELD OF THE INVENTION

Various examples of the current technology relate to methods for storing data in a memory device that includes one or more block(s) which cannot adequately store data (“defective block(s)”).

### BACKGROUND OF THE INVENTION

A memory device may include various levels of hierarchy of data storage. For example, the memory device may include a plurality of channels, with each channel including a plurality of planes, and each plane including a plurality of blocks of data storage. Typically, the memory device stores data in the memory device by issuing a multiplane program command which stores data in all of the planes of a respective one of the channels. Challenges arise in determining the best approach to storing data in the memory device which includes a plurality of defective blocks which cannot adequately store the data.

The background discussion is intended to provide information related to the present technology which is not necessarily prior art.

### SUMMARY OF THE INVENTION

Various examples of the current technology address one or more of the above-mentioned challenges and provide a distinct advance in the art of storing data in a memory device which includes a plurality of defective blocks of data storage. Examples of the current technology provide computer-implemented methods, data storage systems, and computer-readable media that issue a multiplane program command which includes the actual data to be stored in non-defective plane(s) and false data to be stored in one or more defective plane(s) within a channel.

An example of the computer-implemented method broadly comprises identifying a plurality of defective blocks within the memory device; and issuing a multiplane program command that includes actual data to be stored in one or more viable plane(s) and false data to be stored in one or more defective plane(s), the one or more defective plane(s) each including one or more of the plurality of defective blocks.

An example of the data storage system, which includes a controller, broadly comprises memory, a non-volatile memory, and at least one processor. The memory includes instructions stored thereon. The non-volatile memory (NVM) includes a plurality of channels, with each channel including a plurality of logical units, with each logical unit including a plurality of planes, and with each plane including a plurality of blocks of data storage. The instructions, when executed by the at least one processor, cause the at least one processor to: identify a plurality of defective blocks within the memory device; and issue a multiplane program command that includes the actual data to be stored in one or more viable plane(s) and false data to be stored in one or more defective plane(s), the one or more defective plane(s) each including one or more of the plurality of defective blocks.

An example of the computer-readable media has instructions stored thereon, that when executed by at least one processor, cause the at least one processor to: identify a plurality of defective blocks within the memory device; and issue a multiplane program command that includes the actual data to be stored in one or more viable plane(s) and false data to be stored in one or more defective plane(s), the one or more defective plane(s) each including one or more of the plurality of defective blocks.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic block diagram of a host system and a data storage system, each constructed in accordance with various examples of the current technology, the two systems configured to utilize firmware programming to store data in a memory device of the data storage system that includes defective block(s);

FIG. 2 illustrates an example computing system configured to perform operations in accordance with the various examples of the present disclosure;

FIG. 3A includes a table illustrating a logical layout of at least a portion of a non-volatile memory media of the memory device of FIG. 1;

FIG. 3B is a block diagram of additional hierarchy of at least a portion of the non-volatile memory media of the memory device of FIG. 1;

FIG. 4A illustrates a first alternative solution for storing data in a memory device of FIG. 1 that includes a plurality of bad blocks of data storage;

FIG. 4B illustrates a second alternative solution for storing data in the memory device of FIG. 1;

FIG. 4C illustrates a solution of the current technology for storing data in the memory device of FIG. 1; and

FIG. 5 illustrates an example method for storing data in a memory device that includes a plurality of bad blocks of data storage.

The drawing figures do not limit the current technology to the specific examples disclosed and described herein. The drawings are not necessarily to scale, emphasis instead being placed upon clearly illustrating the principles of the technology.

### DETAILED DESCRIPTION OF THE INVENTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

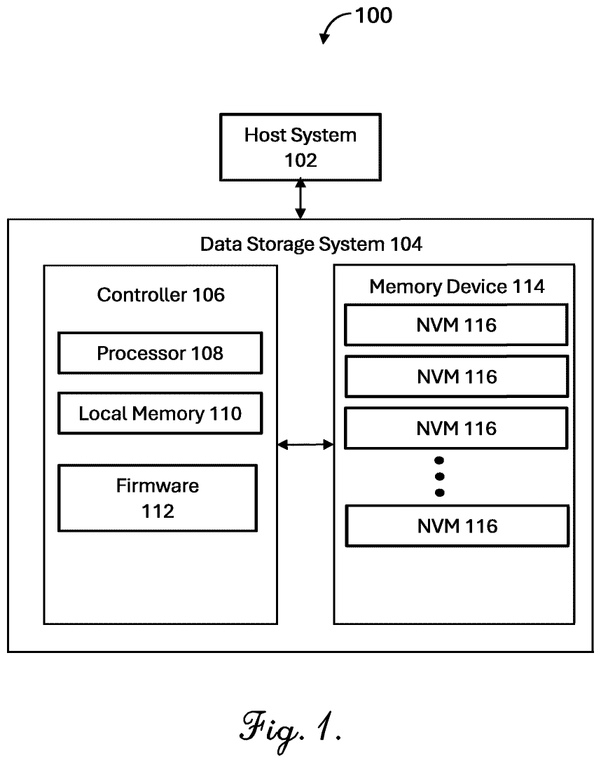

FIG. 1 illustrates an example system 100 including a host system 102 and a data storage system 104. The data storage system 104 may include a controller 106. The controller 106 may include a processor 108, a local memory 110, and firmware 112. The data storage system 104 may also include a memory device 114. The memory device 114 may include a plurality of non-volatile memory (NVM) media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to detect and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

The NVM media 116 further comprises one or more of a plurality of data cell, or memory cell, types-including a single level cell (SLC) memory cell configured to store one (1) bit of data, a multi-level cell (MLC) memory cell configured to store two (2) bits of data, and a triple level cell (TLC) memory cell configured to store three (3) bits of data. The NVM media 116 may also comprise a quad level cell (QLC) memory cell configured to store four (4) bits of data.

The firmware 112 includes instructions, code, code segments, code statements, programs, applications, processes, or the like, any of which may implement algorithms and which control the operation of the controller 106. The firmware 112 may also include data storage, such as a cache memory, or may access the local memory 110, either of which may store a listing of defective or bad block locations in the NVM media 116. The firmware 112 may be stored in a non-transitory computer-readable medium.

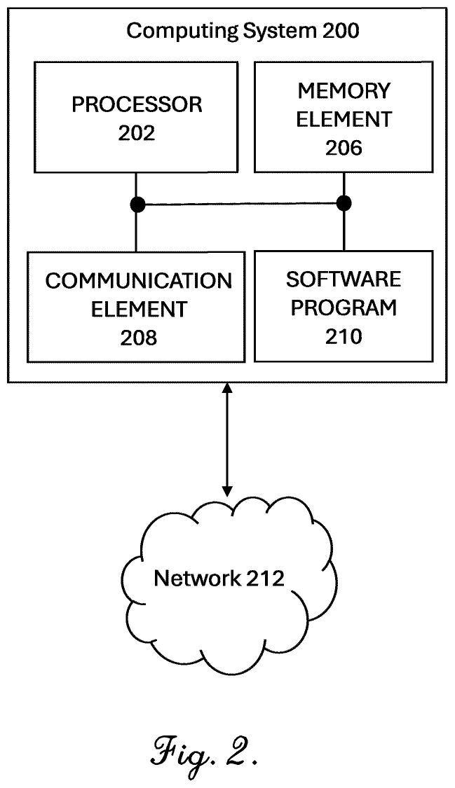

FIG. 2 illustrates a computing system 200 connected to a communication network 212. The computing system 200 may include at least one processor 202, at least one memory element 206, a communication element 208, and a software program 210. In various examples, the computing system 200 may be a host system (e.g. the host system 102 of FIG. 1) and/or a data storage system (e.g. the data storage system 104 of FIG. 1), without limitation.

The software program 210 may be configured with instructions for performing and/or enabling performance of at least some of the steps set forth herein. In an example, the software program 210 comprises instructions stored on computer-readable media of memory element 206. In various examples, the software program 210 may include instructions for performing operations of the firmware 112 discussed with reference to FIG. 1.

The communication network 212 generally allows communication between the computing system 200 and another computing device, such as between a remote host system (e.g. the host system 102), a local host system, and/or a data storage system (e.g. the data storage system 104 of FIG. 1), without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include transmitter(s), receiver(s) and/or transceiver(s). The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard such as WiFi, IEEE 802.16 standard such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain examples, the communication element 208 may also couple with optical fiber cables. The communication element 208 may respectively be in communication with the processor 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some examples, the memory element 206 may be embedded in, or packaged in the same package as, the processor 202. The memory element 206 may include, or may constitute, a “computer-readable medium.” The memory element 206 may store the instructions, code, code segments, software, firmware, programs, applications, apps, services, daemons, or the like that are executed by the processor 202. In an example, the memory element 206 stores the software applications/program 210. The memory element 206 may also store settings, data, documents, sound files, photographs, movies, images, databases, and the like. In various examples, the memory element 206 may include or comprise a first memory component (e.g. the local memory 110 of FIG. 1) and one or more SSDs (e.g. the memory device 114 of FIG. 1).

The processor 202 may include electronic hardware components such as digital processing unit(s), microprocessors (single-core and multi-core), microcontrollers, digital signal processors (DSPs), field-programmable gate arrays (FPGAs), analog and/or digital application-specific integrated circuits (ASICs), or the like, or combinations thereof. The processor 202 may generally execute, process, or run instructions, code, code segments, software, firmware, programs, applications, apps, processes, services, daemons, or the like. For instance, the processor 202 may execute the software applications/program 210. The processor 202 may also include hardware components such as finite-state machines, sequential and combinational logic, and other electronic circuits that can perform the functions necessary for the operation of the current disclosure. The processor 202 may be in communication with the other electronic components through serial or parallel links that include universal busses, address busses, data busses, control lines, and the like. In various examples, the processor 202 may include or comprise the processor 108 of FIG. 1.

Through hardware, software, firmware, or various combinations thereof, the processor 202 may—alone or in combination with other processors—be configured to perform the operations of examples of the present disclosure. The examples described herein in connection with the attached drawing figures are intended to describe aspects of the disclosure in sufficient detail to enable those skilled in the art to practice the disclosure. Other examples can be utilized and changes can be made without departing from the scope of the present disclosure. The system may include additional, less, or alternate functionality and/or device(s), including those discussed elsewhere herein. The above detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

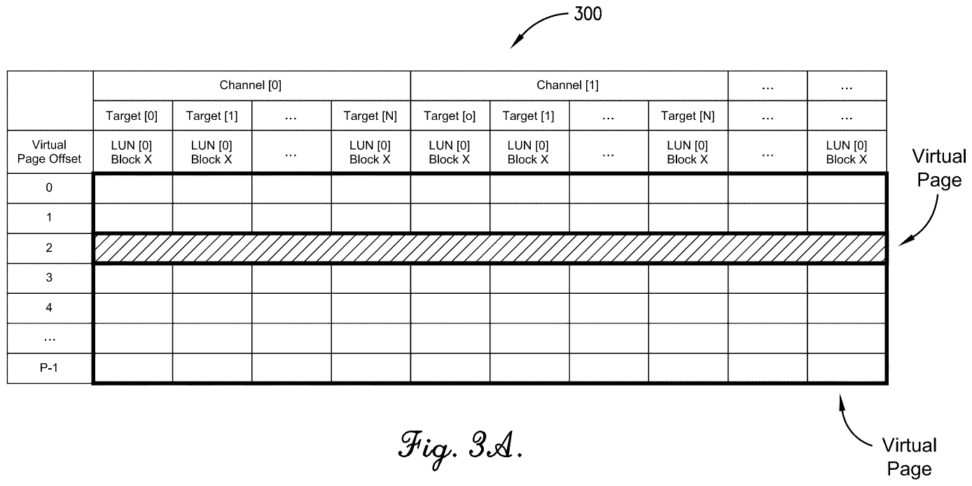

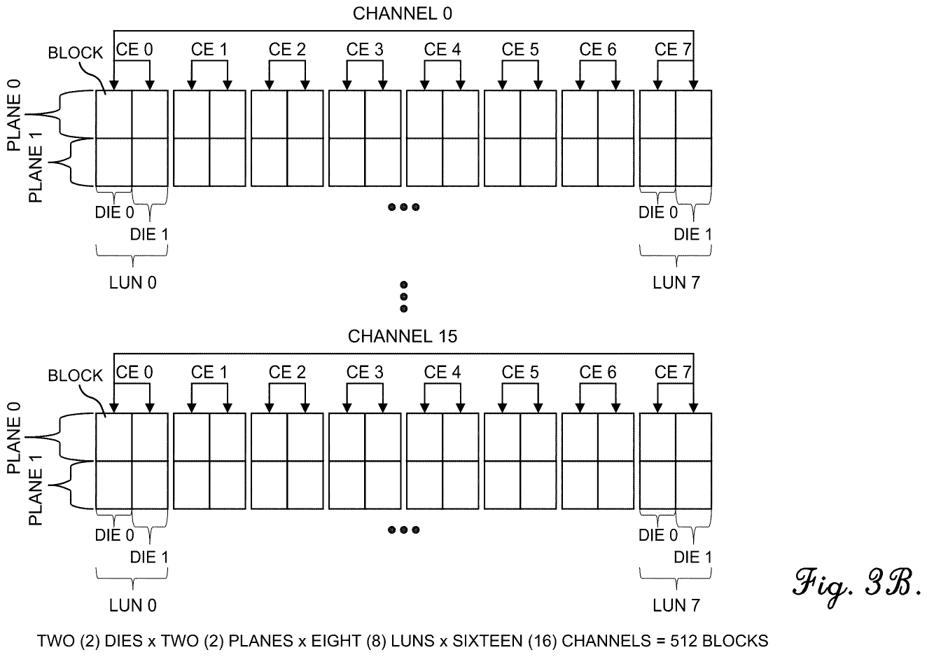

Referring to FIG. 3A, a table 300 illustrates a first logical layout of at least a portion of the NVM media 116 of the memory device 114. The table 300 includes a plurality of columns and a plurality of rows. Headings for the columns include a plurality of channels, with each channel including a plurality of targets, and each target including a logical unit (“LUN”) and a block. Labels for the rows include a plurality of virtual page offsets. Each cell of the table 300 represents one physical block of data storage, whereas all of the cells shown in the table 300 represent one virtual block of data storage, which is equal to 128 physical blocks of data storage. One row of cells in the table 300 represents a virtual page.

Referring to FIG. 3B, a diagram of additional hierarchy of at least a portion of the NVM media 116 of the memory device 114 is shown. The diagram includes a plurality of blocks of data storage distributed in an array. All of the blocks in a row, which in this example includes sixteen (16) blocks, form a plane of data storage. Two (2) blocks in a column form one (1) die, and two (2) dies, DIE 0 and DIE 1, form a LUN, which may include, or be, a physical chip package that retains two (2) chips or dies. Each LUN has a respective one of a plurality of chip enable (CE) lines (CE 0 through CE 7) electrically connected to each die (DIE 0 and DIE 1), wherein each CE line receives a respective one of a plurality of CE signals. In addition, each CE line enables or disables a respective one of the LUNs. Two (2) planes and eight (8) LUNs form a respective one of a plurality of channels, CHANNEL 0 through CHANNEL 15. In the illustrated exemplary diagram of data storage, two (2) dies×two (2) planes×eight (8) LUNs×sixteen (16) channels =512 blocks of data storage, which may form a physical board, such as a printed circuit board or flexible circuit board, or a card of data storage.

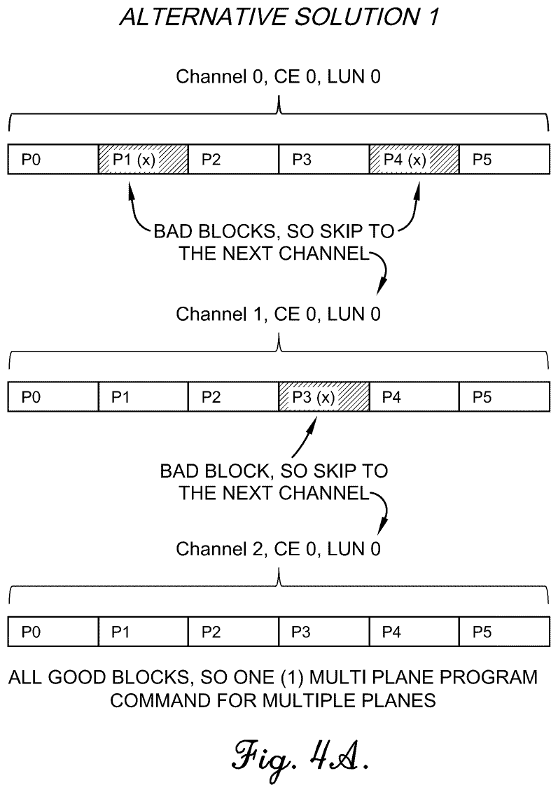

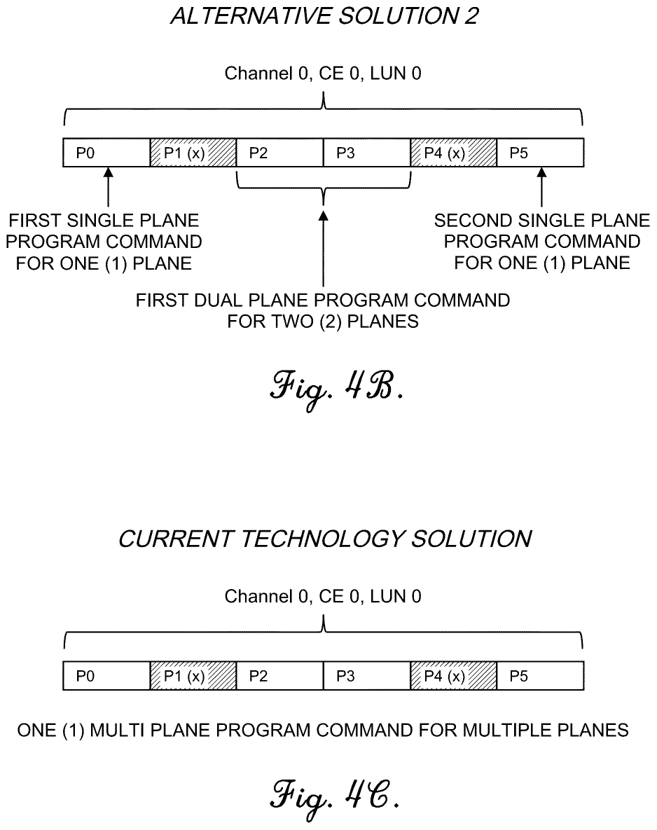

When data is stored in the NVM media 116 of the memory device 114, data may be written to a plurality of blocks at the same time. More specifically, data may be written to all of the blocks in a plane of data storage. In addition, data may be written to all of the planes in a channel of data storage. For example, the controller 106 may issue a single plane program command to store data in all of the blocks of one (1) plane of data storage. A dual plane program command may be issued to store data in all of the blocks of two (2) planes of data storage. A multiplane program command may be issued to store data in all of the blocks of more than two (2) planes of data storage. The multiplane program command may be issued to store data in all of the planes in one (1) channel of data storage. As an example, with reference to FIGS. 4A, 4B, and 4C, one (1) channel of data storage may include six (6) planes of data storage. Thus, the multiplane program command may be issued to store data in the six (6) planes of one (1) channel of data storage. It is possible that in the NVM media 116, one or more blocks within a plane of data storage are bad or defective. Unfortunately, data cannot be adequately stored in the defective blocks.

After manufacturing or fabrication of the memory device 114 or components of the memory device 114, a manufacturer may mark blocks that are known to be defective. During the power on process, i.e., initially applying electric power to, the data storage system 104, the controller 106 may initiate a scan of each block of the memory device 114. Those blocks that are marked as being defective are determined. A listing of the defective blocks may be created. In some instances, the listing may be received from an external source.

A block may also or alternatively be determined to be or identified as “defective” based on one or more metrics of performance and/or duration and/or type of historical usage, such as where the determination is based on a multifactorial standard considering any combination of one or more of errors attributable to the block, number of program/erase (PE) cycles performed by the block, quality of service (QoS) metrics and/or other performance or historical usage factors. The standard(s) or metric(s) for identifying a “defective” block may be set by a manufacturer of the corresponding NVM media, by a manufacturer or designer of one or more controller(s) for the NVM media, and/or otherwise within the scope of the present disclosure. Such defective blocks may be identified in or added to a list of defective blocks. A block may be “identified” as defective through real-time analysis, recognition of a label or flag, by virtue of its inclusion in a list or placement in a database entry, or otherwise, it being understood that the ability to recognize a block as having been categorized as defective is not limited by data format or structure.

Referring to FIG. 4A, a first alternative solution for dealing with defective blocks in a plane during the data storage process is shown. The first alternative solution involves not writing data to the entire channel, i.e., all six (6) planes, if one or more of the planes has one or more defective blocks. Channels with even one (1) defective block are skipped for data storage. In the example shown in FIG. 4A, in a first channel, CHANNEL 0, planes P1 and P4, include defective blocks. Accordingly, the processor 108 and/or 202 does not issue a program command to store data in CHANNEL 0. Likewise, CHANNEL 1 has a bad plane, P3, and thus does not issue a program command to store data in CHANNEL 1. CHANNEL 2, however, has no planes with defective blocks, so the processor 108 and/or 202 issues a program command to store data in CHANNEL 2. The processor 108 and/or 202 issues a multiplane program command to store data in channels that have planes with no defective blocks and skips those channels that have planes with at least one defective block.

Referring to FIG. 4B, a second alternative solution for dealing with defective blocks in a plane during the data storage process is shown. The second alternative solution involves issuing a plurality of single plane program commands and/or multiplane program commands, as needed, to store data in a single channel that has one or more planes with one or more defective blocks. For example, if CHANNEL 0 (including six (6) planes) has two (2) planes, such as plane P1 and plane P4, with defective blocks, then the processor 108 and/or 202 issues a first single plane program command to write data into plane P0. The processor 108 and/or 202 issues a second single plane program command to write data into plane P5. The processor 108 and/or 202 issues a first dual plane program command (for two (2) planes) to write data into plane P2 and plane P3.

The first alternative solution is inefficient because it bypasses the opportunity to store data in viable planes, i.e., planes that do not have identified defective blocks. In the example shown in FIG. 4A, out of the first twelve (12) possible planes of storage, only three (3) had defective blocks. Thus, 75% of the data storage that was good and could have stored data was bypassed. The second alternative solution is inefficient because multiple program commands have to be issued to store data within the same channel.

Referring to FIG. 4C, a solution provided by the current technology is shown. According to various examples, a plurality of defective blocks are identified. In various examples, the defective blocks may be identified to the controller 106 and/or memory device 114 and/or the controller 106 and/or memory device 114 may determine the defective blocks (e.g., by analyzing available performance and/or historical usage data against a metric or standard, as discussed in more detail above). In various examples, the identification of the plurality of defective blocks may be in the form of a listing of a plurality of defective blocks, though any form or format may be used for identifying the defective blocks.

With reference to FIGS. 3A and 3B, an example of the memory device 114 includes a plurality of channels, CHANNEL 0 through CHANNEL 15. Each channel includes a plurality of logical units, LUN 0 through LUN 7, with each LUN being a chip package that includes a plurality of dies, DIE 0 and DIE 1. Each die includes a plurality of planes, PLANE 0 and PLANE 1. It is noted that in other examples, each die includes more than two (2) planes and may include up to six (6) planes or more. Each plane includes at least one block of data storage.

One or more defective plane(s) is determined, each defective plane including one or more defective block(s). The processor 108 and/or 202 determines, or has access to, a listing of a hierarchy of components, including the plane, the die, the CE, the logical unit, and the channel, associated with each block. Thus, the processor 108 and/or 202 determines whether each plane is defective according to whether the plane includes one or more defective blocks.

Actual data to be stored is received or determined. The actual data is real or legitimate data from a user or other source, such as a camera, a microphone, a sensor, a handheld electronic device, the Internet or cloud, and so forth. For example, the actual data may be data intended for future retrieval and provision to the host. The actual data may be received from an external source, and may include image data, audio data, text data, or the like, or combinations thereof, or the actual data may be determined, such as the result of calculations, signal processing, data processing, or the like, or combinations thereof.

A multiplane program command is issued that includes the actual data to be stored in one or more viable plane(s) and false data to be stored in one or more defective plane(s), as discussed in more detail below. “False data” is filler data that is outdated, duplicative, illegitimate and/or that is otherwise is not intended for future retrieval, use and/or provision to the host. In various examples, the false data includes zeros (0) only so that a zero “0” is stored in each bit of the defective blocks. In various examples, other, non-defective blocks of a defective plane also store false data comprising only zeros (0).

The processor 108 and/or 202 determines the next available blocks of data storage are to have data stored in them, or to be programmed. As mentioned above, each block is associated with a respective one of the planes, a respective one of the dies, a respective one of the CEs, a respective one of the LUNs, and a respective one of the channels. Thus, the processor 108 and/or 202 may determine the plane, the die, the CE, the LUN, and the channel that is next available to have data stored in them, or to be programmed.

As an example with reference to FIG. 4C, the blocks of CHANNEL 0, CE 0, LUN 0, planes P0-P5 are to be programmed next. The processor 108 and/or 202 identifies defective blocks therein, e.g., by mapping or otherwise attributing defective blocks to the planes. In various examples, the processor 108 and/or 202 may read a list of defective blocks and compare whether any of the blocks of the planes to be programmed next are on the list. Any planes that include blocks on the list (defective blocks) receive false data, while those planes without defective blocks (i.e., viable planes) receive actual data.

In the current example, plane P1 and plane P4 include blocks that are on the list. Accordingly, the processor 108 and/or 202 issues a multiplane program command that includes actual data to be stored in plane P0, plane P2, plane P3, and plane P5, and false data to be stored in plane P1 and plane P4. It is possible that the processor 108 and/or 202 executes other checks of the data that is stored or programmed. In some instances, the checks may determine that the data written to the defective blocks failed to store. However, the data write failure is ignored.

The processor 108 and/or 202 may receive or determine additional actual data to be stored and issue a second multiplane program command for the next available channel as necessary to store data until no more data to be stored is received or determined, in the manner discussed above in connection with a first channel.

The firmware 112 includes instructions, code, code segments, code statements, programs, applications, processes, or the like for executing this process. For example, the firmware algorithm may issue the multiplane programming command for a channel that includes one or more defective blocks, whereby data buffers with 0×00 content are used for writing to the defective blocks. Accordingly, redundant array of independent disks (RAID) protection may be maintained. In addition, the firmware 112 may include data storage, such as a cache memory, or may access the local memory 110, either of which may store a listing of all of the defective blocks in the memory device 114.

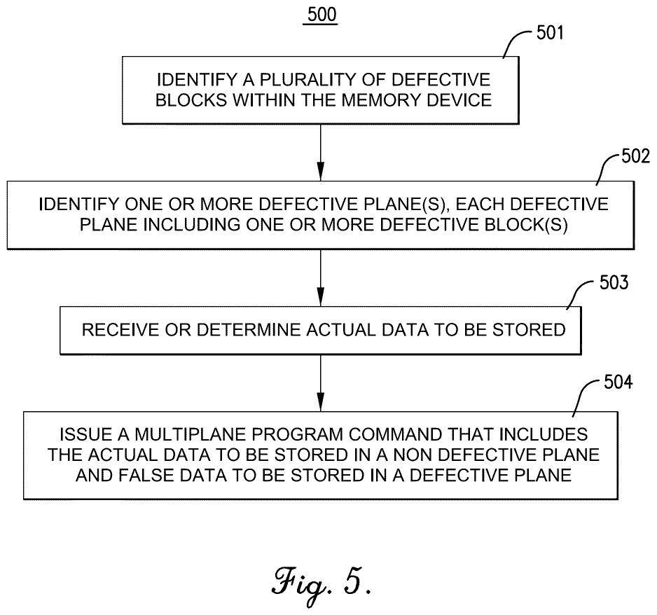

FIG. 5 depicts a listing of at least a portion of the steps of an exemplary computer-implemented method 500 for storing data in a memory device (e.g., memory device 114) that includes a plurality of planes of data storage. Variations to the steps may be performed. The steps may be performed in the order shown in FIG. 5, or they may be performed in a different order. Furthermore, some steps may be performed concurrently as opposed to sequentially. In addition, some steps may be optional or may not be performed. The steps may be performed by the processor 108 and/or 202 via hardware, software, firmware, or combinations thereof. Also, the steps may be implemented as instructions, code, code segments, code statements, a program, an application, an app, a process, a service, a daemon, or the like, and may be stored on a computer-readable storage medium, such as the local memory 110 and/or the memory element 206.

Referring to step 501, a plurality of defective blocks within the memory device 114 is identified. With reference to FIGS. 3A and 3B, an example of the memory device 114 includes a plurality of channels, CHANNEL 0 through CHANNEL 15. Each channel includes a plurality of logical units, LUN 0 through LUN 7, with each LUN being a chip package that includes a plurality of dies, DIE 0 and DIE 1. Each die includes a plurality of planes, PLANE 0 and PLANE 1. It is noted that in other examples, each die includes more than two (2) planes and may include up to six (6) planes or more. Each plane includes at least one block of data storage.

Referring to step 502, one or more defective plane(s) is identified, each defective plane including one or more defective block(s). The processor 108 and/or 202 determines, or has access to, a listing of a hierarchy of components, including the plane, the die, the chip enable, the logical unit, and the channel, associated with each block. Thus, the processor 108 and/or 202 determines whether each plane is defective according to whether the plane includes one or more defective blocks.

Referring to step 503, actual data to be stored is received or determined. The actual data may be received from an external source, such as a host, and may include image data, audio data, text data, or the like, or combinations thereof, or the actual data may be determined, such as the result of calculations, signal processing, data processing, or the like, or combinations thereof.

Referring to step 504, a multiplane program command is issued that includes the actual data to be stored in a non-defective plane and false data to be stored in a defective plane. The processor 108 and/or 202 determines the next available blocks of data storage are to have data stored in them, or to be programmed. As mentioned above, each block is associated with a respective one of the planes, a respective one of the dies, a respective one of the CEs, a respective one of the LUNs, and a respective one of the channels. Thus, the processor 108 and/or 202 may determine the plane, the die, the CE, the LUN, and the channel that is next available to have data stored in them, or to be programmed. As an example with reference to FIG. 4C, the blocks of CHANNEL 0, CE 0, LUN 0, planes P0-P5 are to be programmed next. The processor 108 and/or 202 may read a listing of defective blocks to compare whether any of the blocks of the planes to be programmed next are on the list. Any planes that include blocks on the list receive false data, while those planes not including blocks on the list receive actual data. In the current example, plane P1 and plane P4 include blocks that are on the list. Accordingly, the processor 108 and/or 202 issues a multiplane program command that includes actual data to be stored in plane P0, plane P2, plane P3, and plane P5 and false data to be stored in plane P1 and plane P4. In various examples, the false data includes zeros (0) only so that a zero “0” is stored in each bit of the defective blocks.

The method 500 continues with a repetition of steps 503 and 504, with the processor 108 and/or 202 issuing a multiplane program command for the next available channel as necessary to store data until no more data to be stored is received or determined.

Throughout this specification, references to “one example”, “an example”, or “examples” mean that the feature or features being referred to are included in at least one example of the technology. Separate references to “one example”, “an example”, or “examples” in this description do not necessarily refer to the same example and are also not mutually exclusive unless so stated and/or except as will be readily apparent to those skilled in the art from the description. For example, a feature, structure, act, etc. described in one example may also be included in other examples, but is not necessarily included. Thus, the current technology can include a variety of combinations and/or integrations of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain examples are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In examples, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various examples, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering examples in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In examples in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some examples, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some examples, the processors may be located in a single location (e.g., within a home environment, an office environment or as a server farm), while in other examples the processors may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A computer-implemented method for storing data in a memory device that includes a plurality of planes of data storage, each plane including a plurality of blocks of data storage, the computer-implemented method comprising:
identifying a plurality of defective blocks within the memory device; and
issuing a multiplane program command that includes actual data to be stored in one or more viable plane(s) and false data to be stored in one or more defective plane(s), the one or more defective plane(s) each including one or more of the plurality of defective blocks.

2. The computer-implemented method of claim 1, further comprising identifying the one or more defective plane(s).

3. The computer-implemented method of claim 1, further comprising receiving or determining the actual data to be stored.

4. The computer-implemented method of claim 1, wherein the multiplane program command is issued for the one or more non-defective plane(s) and the one or more defective plane(s) within a channel of data storage.

5. The computer-implemented method of claim 4, further comprising determining the next available channel to have data stored.

6. The computer-implemented method of claim 5, further comprising repeating the following until no more data to be stored is received or determined:
receiving or determining additional actual data to be stored;
determining the next available channel to have data stored; and
issuing a multiplane program command that includes the additional actual data to be stored in one or more non-defective plane(s) within the next available channel and additional false data to be stored in one or more defective plane(s) within the next available channel.

7. The computer-implemented method of claim 1, wherein the false data to be stored in the one or more defective plane(s) includes a plurality of zeros (0) only.

8. A data storage system including a controller, the data storage system comprising:
memory including instructions stored thereon;
a non-volatile memory (NVM) including a plurality of channels, each channel including a plurality of logical units, each logical unit including a plurality of planes, and each plane including a plurality of blocks of data storage; and
at least one processor, wherein the instructions, when executed by the at least one processor, cause the at least one processor to:
identify a plurality of defective blocks within the memory device; and
issue a multiplane program command that includes actual data to be stored in one or more viable plane(s) and false data to be stored in one or more defective plane(s), the one or more defective plane(s) each including one or more of the plurality of defective blocks.

9. The data storage system of claim 8, wherein the instructions, when executed by the at least one processor, further cause the at least one processor to identify the one or more defective plane(s).

10. The data storage system of claim 8, wherein the instructions, when executed by the at least one processor, further cause the at least one processor to receive or determine the actual data to be stored.

11. The data storage system of claim 8, wherein the multiplane program command is issued by the at least one processor for the one or more non-defective plane(s) and the one or more defective plane(s) within a channel of data storage.

12. The data storage system of claim 11, wherein the instructions, when executed by the at least one processor, further cause the at least one processor to determine the next available channel to have data stored.

13. The data storage system of claim 12, wherein the instructions, when executed by the at least one processor, further cause the at least one processor to perform the following until no more data to be stored is received or determined:
receive or determine additional actual data to be stored;
determine the next available channel to have data stored; and
issue a multiplane program command that includes the additional actual data to be stored in one or more non-defective plane(s) within the next available channel and additional false data to be stored in one or more defective plane(s) within the next available channel.

14. The data storage system of claim 8, wherein the false data to be stored in the one or more defective plane(s) includes a plurality of zeros (0) only.

15. Non-transitory computer readable media having instructions stored thereon, that when executed by at least one processor, cause the at least one processor to:
identify a plurality of defective blocks within the memory device; and
issue a multiplane program command that includes actual data to be stored in one or more viable plane(s) and false data to be stored in one or more defective plane(s), the one or more defective plane(s) each including one or more of the plurality of defective blocks.

16. The non-transitory computer readable media of claim 15, wherein the instructions, when executed by the at least one processor, further cause the at least one processor to
identify the one or more defective plane(s); and
receive or determine the actual data to be stored.

17. The non-transitory computer readable media of claim 15, wherein the multiplane program command is issued by the at least one processor for the one or more non-defective plane(s) and the one or more defective plane(s) within a channel of data storage.

18. The non-transitory computer readable media of claim 17, wherein the instructions, when executed by the at least one processor, further cause the at least one processor to determine the next available channel to have data stored.

19. The non-transitory computer readable media of claim 18, wherein the instructions, when executed by the at least one processor, further cause the at least one processor to perform the following until no more data to be stored is received or determined:
receive or determine additional actual data to be stored;
determine the next available channel to have data stored; and
issue a multiplane program command that includes the additional actual data to be stored in one or more non-defective plane(s) within the next available channel and additional false data to be stored in one or more defective plane(s) within the next available channel.

20. The non-transitory computer readable media of claim 15, wherein the false data to be stored in the one or more defective plane(s) includes a plurality of zeros (0) only.
